(19) United States
(12) Patent Application Publication
(10) Pub. No.: US 2012/0211072 A1
(43) Pub. Date: Aug. 23, 2012

(54) Solar Cell And Method Of Manufacturing Same

(75) Inventors: Deok-Kee Kim, Yongin-si (KR); Yun Gi Kim, Yongin-si (KR); Dongkyun Kim, Suwon-si (KR); Young Moon Choi, Seoul (KR); Eun Cheol Do, Yongin-si (KR)

(73) Assignee: SAMSUNG ELECTRONICS CO., LTD., Suwon-si (KR)

(21) Appl. No.: 13/236,030

(22) Filed: Sep. 19, 2011

(30) Foreign Application Priority Data
Feb. 21, 2011 (KR) 10-2011-0015152

(51) Int. Cl. H01L 31/0216; H01L 31/18

(52) U.S. Cl. 136/256; 438/98; 257/E31.124

(57) ABSTRACT

Example embodiments of a solar cell including a semiconductor substrate, an N emitter layer formed on a light-absorbing surface of the semiconductor substrate, a p+ region formed on the light-absorbing surface of the semiconductor substrate, a first electrode electrically connected to the p+ region, a second electrode separately formed from the first electrode on the light-absorbing surface of the semiconductor substrate and electrically connected to the N emitter layer, and an auxiliary layer inducing an N+ back surface field (BSF) on the opposite surface to the light-absorbing surface of the semiconductor substrate, and a method of manufacturing the solar cell are provided.

### CROSS-REFERENCE TO RELATED APPLICATION

This application claims priority to and the benefit of Korean Patent Application No. 10-2011-0015152 filed in the Korean Intellectual Property Office on Feb. 21, 2011, the entire contents of which is incorporated herein in its entirety by reference.

### BACKGROUND

1. Field

Example embodiments relate to solar cells and methods for manufacturing the same.

2. Description of the Related Art

A solar cell is a photoelectric conversion device that transforms solar energy into electrical energy, and has attracted much attention as an infinite but pollution-free next generation energy source.

A solar cell may include p-type and n-type semiconductors and produces electrical energy by transferring electrons and holes to the n-type and p-type semiconductors, respectively, and then collecting electrons and holes in each electrode when an electron-hole pair (EHP) is produced by light energy absorbed in a photoactive layer inside the semiconductors.

Further, a solar cell is preferably efficient at producing electrical energy from solar energy. Increasing the generation of electron-hole pairs and reducing the recombination of electron-hole pairs may increase the efficiency of a solar cell.

### SUMMARY

Provided are solar cells having improved efficiency, due to decreasing the recombination of electrons and holes at a rear side of a semiconductor substrate, and methods for manufacturing solar cells.

According to example embodiments, a solar cell is provided that includes a semiconductor substrate, an N emitter layer formed on a light-absorbing surface of the semiconductor substrate, a p+ region formed on the light-absorbing surface of the semiconductor substrate, a first electrode electrically connected to the p+ region, a second electrode separately formed from the first electrode on the light-absorbing surface of the semiconductor substrate and electrically connected to the N emitter layer, and an auxiliary layer inducing an N+ back surface field (BSF) on the opposite side to the light-absorbing surface of the semiconductor substrate.

The solar cell may further include a spacer between the N emitter layer and the first electrode. The spacer may include a material selected from one of aluminum oxide (Al₂O₃), silicon oxide (SiO₂), titanium oxide (TiO₂ or TiO₄), magnesium oxide (MgO), cerium oxide (CeO₂), aluminum nitride (AlN), silicon nitride (SiNₓ), aluminum oxynitride (AlON), silicon oxynitride (SiON), titanium oxynitride (TiON), and a combination thereof.

The N emitter layer may be separated from the p+ region and the first electrode.

The auxiliary layer may include one of an n+ layer, a dielectric layer having a positive fixed charge, a positive (+) voltage-applied reflective layer, and a combination thereof.

The n+ layer may be formed by a process including one of: (i) a vapor diffusion method using one of PH₃, AsH₃, SbCl₃, POCl₃, and a combination thereof; (ii) a solid-phase diffusion method using one of phosphosilicate glass (PSG), arsenic silicon glass (ASG), and a combination thereof; (iii) an ion implantation method using one of arsenic (As), phosphorus (P), and a combination thereof; and (iv) a combination thereof.

The n+ layer may have a doping concentration of about 1×10¹⁶ cm⁻³ to about 1×10²¹ cm⁻³, and may include a sheet resistance of about 10 Ω to about 90,000 Ω.

The dielectric layer may include one of an oxide, a nitride, an oxynitride, and a combination thereof. The dielectric layer may have a positive fixed charge density of about 1×10¹⁰ cm⁻² to about 1×10¹⁵ cm⁻². The dielectric layer may have a thickness of about 1 nm to about 10,000 nm.

The reflective layer may include one of Al, Au, Pt, Ag, Cu, and a combination thereof. The reflective layer may be configured to receive an applied voltage of about +0.1 V to about +50 V. The reflective layer may have a thickness of about 1 nm to about 10,000 nm.

According to example embodiments, a method of manufacturing a solar cell is provided that includes preparing a semiconductor substrate, forming an N emitter layer on a light-absorbing surface of the semiconductor substrate, forming an auxiliary layer inducing an N+ back surface field (BSF) on an opposite surface to the light-absorbing surface of the semiconductor substrate, forming a p+ region on the light-absorbing surface of the semiconductor substrate, forming a first electrode electrically connected to the p+ region, and forming a second electrode separate from the first electrode on the light-absorbing surface of the semiconductor substrate and electrically connected to the N emitter layer.

The auxiliary layer may include one of an n+ layer, a dielectric layer including a positive fixed charge, a positive (+) voltage-applied reflective layer, and a combination thereof. The n+ layer, the dielectric layer, and the reflective layer may be the same as described above.

Other example embodiments will be described in the following detailed description.

### BRIEF DESCRIPTION OF THE DRAWINGS

The foregoing and other features and advantages of example embodiments will be apparent from the more particular description of non-limiting embodiments, as illustrated in the accompanying drawings in which like reference characters refer to the same parts throughout the different views. The drawings are not necessarily to scale, emphasis instead being placed upon illustrating the principles of the inventive concepts. In the drawings:

FIG. 1 is a cross-sectional view of a solar cell according to example embodiments.

FIGS. 2A to 2G are cross-sectional views that sequentially show a process of manufacturing a solar cell according to example embodiments.

FIG. 3 is a cross-sectional view of a solar cell according to example embodiments.

FIGS. 4A to 4F are cross-sectional views that sequentially show a process of manufacturing a solar cell according to example embodiments.

### DETAILED DESCRIPTION

Example embodiments will hereinafter be described in detail referring to the following accompanied drawings, in which example embodiments are shown. Example embodiments, may, however, be embodied in many different forms and should not be construed as being limited to the example embodiments set forth herein; rather, these example embodiments are provided so that this disclosure will be thorough and complete, and will fully convey concepts of example embodiments to those of ordinary skill in the art. In the drawings, the thickness of layers, films, panels, regions, etc., are exaggerated for clarity. Like reference numerals designate like elements throughout the specification, and thus their description will be omitted.

It will be understood that when an element such as a layer, film, region, or substrate is referred to as being “on” another element, it can be directly on the other element or intervening elements may also be present. In contrast, when an element is referred to as being “directly on” another element, there are no intervening elements present. It will be also understood that when an element such as a layer, film, region, or substrate is referred to as being “under” another element, it may be directly under the other element or intervening elements may also be present.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

According to example embodiments, a solar cell may include a semiconductor substrate, an N emitter layer formed on a light-absorbing surface of the semiconductor substrate, a p+ region formed on the light-absorbing surface of the semiconductor substrate, a first electrode electrically connected to the p+ region, a second electrode separately formed from the first electrode on the light-absorbing surface of the semiconductor substrate and electrically connected to the N emitter layer; and an auxiliary layer inducing an N+ back surface field (BSF) on the opposite surface to the light-absorbing surface of the semiconductor substrate. The auxiliary layer may include an n+ layer, a dielectric layer having a positive fixed charge, a positive (+) voltage-applied reflective layer, or a combination thereof.

On the rear side of the semiconductor substrate, the surface recombination velocity (Srv) of a hole is about 1/100 of the surface recombination velocity (Srv) of an electron. In addition, the surface recombination of electrons and holes is restricted by concentration of a minority carrier on the rear side of the semiconductor substrate.

When a solar cell includes an auxiliary layer inducing an N+ back surface field (BSF) on the rear side of a semiconductor substrate as aforementioned, electrons are included by the N+ back surface field (BSF) and become a majority carrier on the rear side of the semiconductor substrate, while holes become a minority carrier. In addition, the N+ back surface field (BSF) may further decrease concentration of holes on the rear side of the semiconductor substrate. Accordingly, the recombination of electrons and holes may also be decreased on the rear side of the semiconductor substrate, increasing the open circuit voltage (Voc), and thus improving efficiency of a solar cell.

On the other hand, when a solar cell includes a p+ layer doped with p-type impurity formed on the rear side of the semiconductor layer, a P+ back surface field (BSF) is induced. Accordingly, since holes are induced on the rear side of the semiconductor layer and become a majority carrier, the recombination of electrons and holes is harder to decrease on the rear side of the semiconductor layer.

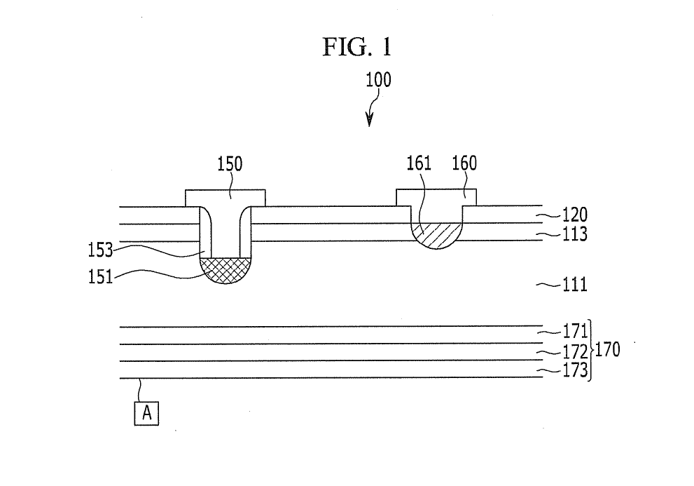

FIG. 1 is a cross-sectional view showing a solar cell 100 according to example embodiments.

Hereinafter, the side of a semiconductor layer 111 that receives solar energy (a light-absorbing surface) is called the front side, while the other side of the semiconductor layer 111 is called the rear side. In addition, for better understanding and ease of description, the relationship between the upper and lower positions is described from the center of the semiconductor layer 111, but is not limited thereto.

Referring to FIG. 1, a solar cell 100 according to example embodiments may include: a semiconductor layer 111; an N emitter layer 113 on the front side of the semiconductor layer 111; an anti-reflection coating layer 120 on the front side of the N emitter layer 113; a p+ region 151 penetrating the anti-reflection coating layer 120 and the N emitter layer 113 and contacting semiconductor layer 111 on the front side of the semiconductor layer 111; a spacer 153 contacting the anti-reflection coating layer 120, the N emitter layer 113, the semiconductor layer 111, and the p+ region 151 where it is penetrated to form the p+ region 151; a first electrode 150 electrically connected to the p+ region 151; an n+ region 161 separately formed from the p+ region 151 on the front side of the semiconductor layer 111 and penetrating the anti-reflection coating layer 120 and thus is electrically connected to the semiconductor layer 111; a second electrode 160 electrically connected to the n+ region 161; and an auxiliary layer 170 inducing an N+ back surface field (BSF) on the rear side of the semiconductor layer 111. The auxiliary layer 170 may include an n+ layer 171, a dielectric layer 172 having a positive fixed charge, a positive (+) voltage-applied reflective layer 173, or a combination thereof. The reflective layer 173 is connected to an electricity supplier A applying a positive (+) voltage.

FIG. 1 shows an anti-reflection coating layer 120 and an n+ region 161, but is not limited thereto. The anti-reflection coating layer 120 and the n+ region 161 may be selectively omitted.

In addition, FIG. 1 shows an n+ layer 171, a dielectric layer 172 having a positive fixed charge, and a positive (+) voltage-applied reflective layer 173, but is not limited thereto. The n+ layer 171, the dielectric layer 172 having a positive fixed charge, and the positive (+) voltage-applied reflective layer 173 may be selectively omitted. When the positive (+) voltage-applied reflective layer 173 is omitted, an electricity supplier A applying a positive (+) voltage to the reflective layer 173 is also omitted. On the other hand, when the dielectric layer 172 having a positive fixed charge is omitted, an insulation layer having no positive fixed charge may be included.

The semiconductor substrate 111 may be formed of a crystalline silicon or a compound semiconductor. The crystalline silicon may be, for example, a silicon wafer. The semiconductor layer 111 may be doped with a p-type impurity, or may be doped with an n-type impurity. Herein, the p-type impurity may be a material including a Group III element such as boron (B), aluminum (Al), gallium (Ga), and the like, and the n-type impurity may be a material including a Group V element such as phosphorus (P), arsenic (As), antimony (Sb), and the like, but example embodiments are not limited thereto.

The semiconductor layer 111 may have a textured surface at the front side. The semiconductor layer 111 with the textured surface may have protrusions and depressions such as in a pyramid shape, or a porous structure such as a honeycomb structure. A semiconductor 111 with a textured surface may improve efficiency of the solar cell by increasing light absorption and reducing reflectance.

Then, an N emitter layer 113 is formed on the front side of the semiconductor layer 111. The N emitter layer 113 is doped with an n-type impurity and thus may collect the produced electrons toward the second electrode 160.

On the N emitter layer 113, an anti-reflection coating layer 120 is formed. FIG. 1 shows that a solar cell 100 including the anti-reflection coating layer 120, but the anti-reflection coating layer 120 is not limited thereto and may be omitted.

The anti-reflection coating layer 120 may be made of an insulating material that reduces light reflection, for example, an oxide such as aluminum oxide (Al₂O₃), silicon oxide (SiO₂), titanium oxide (TiO₂ or TiO₄), magnesium oxide (MgO), cerium oxide (CeO₂), or a combination thereof, a nitride such as aluminum nitride (AlN), silicon nitride (SiNₓ), titanium nitride (TiN), or a combination thereof, and an oxynitride such as aluminum oxynitride (AlON), silicon oxynitride (SiON), titanium oxynitride (TiON), or a combination thereof. The anti-reflection coating 120 may be formed in a single layer or a plurality of layers.

The anti-reflection coating layer 120 may have a thickness of about 5 nm to about 300 nm, and about 50 nm to about 80 nm in example embodiments.

The anti-reflection coating layer 120 on the front surface of the semiconductor substrate 111 decreases the reflectance of light on the surface of the solar cell and increases the selectivity of a certain wavelength region. In addition, it is possible to increase the efficiency of the solar cell by improving the contact characteristic with silicon present in the front surface of the semiconductor substrate 111.

Then, a p+ region 151 is formed to penetrate the anti-reflection coating layer 120 and the N emitter layer 113 and contact the semiconductor layer 111 on the front side of the semiconductor layer 111. Since the p+ region 151 includes p-type impurities, it may collect the produced holes into the first electrode 150.

Next, a spacer 153 is formed to contact the anti-reflection coating, layer 120, the N emitter layer 113, the semiconductor layer 111, and an upper surface of the p+ region 151. The spacer 153 may include an insulating material that blocks the first electrode 150 from directly contacting the N emitter layer 113.

In particular, the spacer 153 may include: an oxide such as aluminum oxide (Al₂O₃), silicon oxide (SiO₂), titanium oxide (TiO₂ or TiO₄), magnesium oxide (MgO), cerium oxide (CeO₂), or a combination thereof; an nitride such as aluminum nitride (AlN), silicon nitride (SiNₓ), or a combination thereof; an oxynitride such as aluminum oxynitride (AlON), silicon oxynitride (SiON), titanium oxynitride (TiON), or a combination thereof; or a combination thereof.

On the p+ region 151, the first electrode 150 is formed. The first electrode 150 may play a role in collecting holes, and may be formed of a metal such as aluminum (Al) and the like but example embodiments are not limited thereto.

On the semiconductor layer 111, an n+ region 161 is separately formed from the p+ region 151 and penetrates the anti-reflection coating layer 120 and is electrically connected to the semiconductor layer 111. The n+ region 161 is doped with an n-type impurity and may collect produced electrons toward the second electrode 160.

On the n+ region 161, the second electrode 160 is formed. The second electrode 160 may play a role in collecting electrons produced from the semiconductor layer 111 and delivering the electrons to the outside. The second electrode 160 may be made of a metal such as aluminum (Al) and the like but example embodiments are not limited thereto.

An auxiliary layer 170 that induces a N+back surface field (BSF) may be formed on the rear side of the semiconductor layer 111. The auxiliary layer 170 induces electrons gathered on the rear side of the semiconductor layer 111 and plays a role of making holes a minority carrier on the rear side of semiconductor layer 111.

In FIG. 1, the auxiliary layer 170 includes an n+ layer 171, a dielectric layer 172 having a positive fixed charge, and a positive (+) voltage-applied reflective layer 173, but example embodiments are not limited thereto. The n+ layer 171, the dielectric layer 172, and the reflective layer 173 may be selectively omitted.

Hereinafter, the n+ layer 171, the dielectric layer 172 having a positive fixed charge, and the positive (+) voltage-applied reflective layer 173 will be illustrated in detail.

On the rear side of the semiconductor layer 111, an n+ layer 171 is formed. The n+ layer 171 is doped with n-type impurity and plays a role collecting electrons produced on the rear side of the semiconductor layer 111.

On the other hand, when a p+ layer doped with p-type impurity is formed on the rear side of the semiconductor layer 111, a P+ back surface field (BSF) is induced. Accordingly, since holes are induced on the rear side of the semiconductor layer 111 and become a majority carrier, the recombination of electrons and holes is hard to decrease on the rear side of the semiconductor layer 111.

Hereinafter, n-type impurity and p-type impurity are the same as aforementioned, so further description is omitted.

In particular, the n+layer 171 may be formed by various methods: a vapor diffusion method using PH₃, AsH₃, SbCl₃, POCl₃, or a combination thereof; a solid-phase diffusion method using phosphosilicate glass (PSG), arsenic silicon glass (ASG), or a combination thereof; an ion implantation method using arsenic (As), phosphorus (P), or a combination thereof; or a combination thereof.

The n+ layer 171 may have a doping concentration of about 1×10¹⁶ cm⁻³ to about 1×10²¹ cm⁻³. In particular, the n+ layer 171 may have a doping concentration ranging from about 1×10¹⁷ cm⁻³ to about 1×10²⁰ cm⁻³, and more particularly, from about 1×10¹⁸ cm⁻³ to about 1×10¹⁹ cm⁻³.

The n+ layer 171 may have sheet resistance ranging from about 10 Ω to about 90,000 Ω. In particular, the n+ layer 171 may have sheet resistance ranging from about 50 Ω to about 2000 Ω.

On the rear side of the n+ layer 171, a dielectric layer 172 having a positive fixed charge is formed. When the dielectric layer 172 has a positive fixed charge on the surface, the electrons produced are collected toward the rear side of the semiconductor layer 111.

In addition, the dielectric layer 172 may reflect light penetrating the semiconductor layer 111 toward the semiconductor layer 111 for re-absorption, and thus may prevent light loss and increase efficiency of a solar cell.

The dielectric layer 172 may include a material having positive fixed charges, for example, an oxide with a predetermined composition, a nitride with a predetermined composition, an oxynitride with a predetermined composition, or a combination thereof, but is not limited thereto. For example, the nitride may have a positive fixed charge by controlling a ratio between x and y in a nitride such as SiₓN_{y}. In particular, when x<y, the nitride may have a positive fixed charge. Likewise, a material such as AlₓO_{y}, SiₓO_{y}, SiₓO_{y}N_{z}, and the like may have a positive fixed charge by controlling a ratio among x, y, and z. In particular, a material having a positive fixed charge, which is included in a dielectric layer 172, may include silicon oxide (SiO₂), silicon nitride (Si₃N₄), and zirconium oxide (ZrO₂).

The dielectric layer 172 may have a positive fixed charge density ranging from about 1×10¹⁰ cm⁻² to about 1×10¹⁵ cm⁻². When the dielectric layer 172 has a positive fixed charge density within the range, the produced electrons are induced on the rear side of the semiconductor layer 111 and thus are less likely to recombine with electrons and holes on the surface. In particular, the dielectric layer 172 may have a positive fixed charge density ranging from about 1×10¹¹ cm⁻² to about 1×10¹³ cm⁻².

The dielectric layer 172 may be formed into a single layer or multi-layers, and may have a thickness ranging from about 1 nm to about 10,000 nm. When the dielectric layer 172 has a thickness within the aforementioned range, the produced electrons may be induced on the rear side of the semiconductor layer 111 and thus may recombine with electrons and holes less on the semiconductor 111 surface. In particular, the dielectric layer 172 may have a thickness ranging from about 10 nm to about 100 nm.

On the rear side of the dielectric layer 172, a positive (+) voltage-applied reflective layer 173 is formed. The reflective layer 173 is connected to an electricity supplier A applying a positive (+) voltage.

When a positive (+) voltage is applied to the reflective layer 173, the produced electrons are collected toward the rear side of a semiconductor layer 111. In addition, the reflective layer 173 reflects light passing the semiconductor layer 111 toward the semiconductor layer 111 again to reabsorb light, and thus prevents light loss and increases efficiency of a solar cell.

The reflective layer 173 may be applied with a voltage ranging from about +0.1 V to about +50 V. When the reflective layer 173 is applied with a voltage within the range, the produced electrons may be induced on the rear side of the semiconductor layer 111 and thus are less likely to recombine with electrons and holes on the semiconductor layer 111 surface. In particular, the reflective layer 173 may be applied with a voltage ranging from about +0.5 V to about +10 V.

The reflective layer 173 may include a conductive material, for example Al, Au, Pt, Ag, Cu, or a combination thereof, but is not limited thereto.

The reflective layer 173 may have a thickness of about 1 nm to about 10,000 nm. When the reflective layer 173 has a thickness within the aforementioned range, the produced electrons may be induced on the rear side of the semiconductor layer 111 and are less likely to recombine with electrons and holes on the semiconductor layer 111 surface. In particular, the reflective layer 173 may have a thickness ranging from about 10 nm to about 1000 nm.

According to example embodiments, a method of manufacturing the solar cell may include: providing a semiconductor substrate; forming an N emitter layer on the light-absorbing surface of the semiconductor substrate; forming an auxiliary layer inducing an N+ back surface field (BSF) on the opposite side to the light-absorbing surface of the semiconductor substrate; forming a p+ region on the light-absorbing surface of the semiconductor substrate; forming a first electrode electrically connected to the p+ region; and forming a second electrode separately formed from the first electrode on the light-absorbing surface of the semiconductor substrate and electrically connected to the N emitter layer.

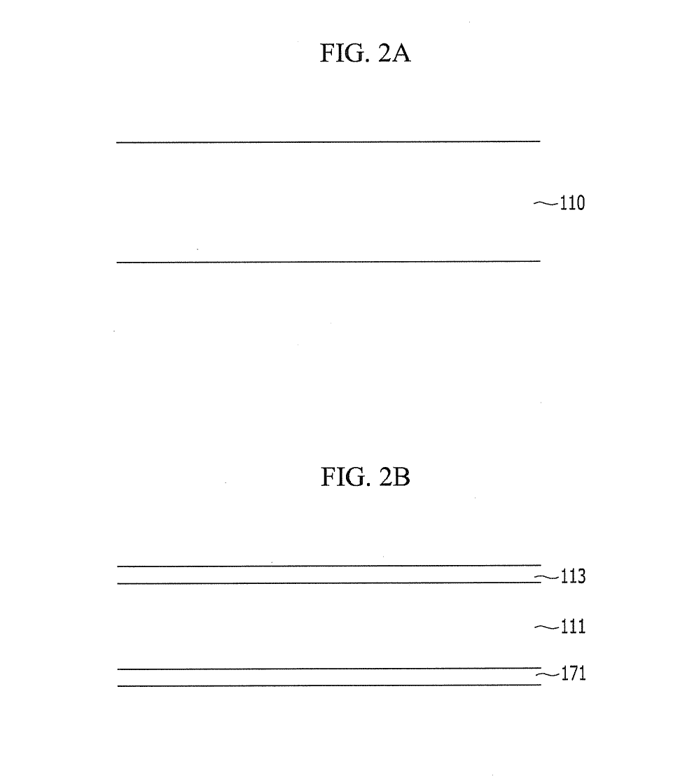

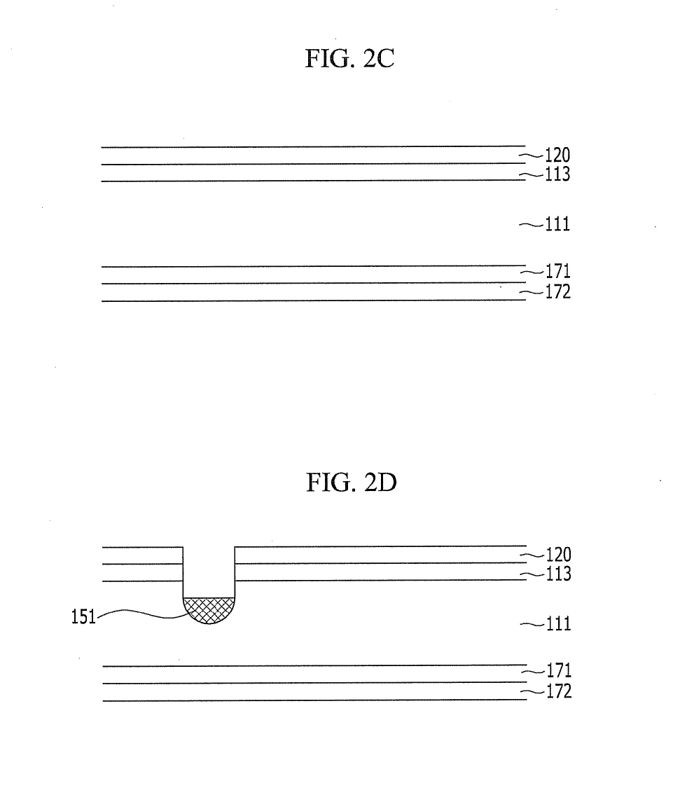

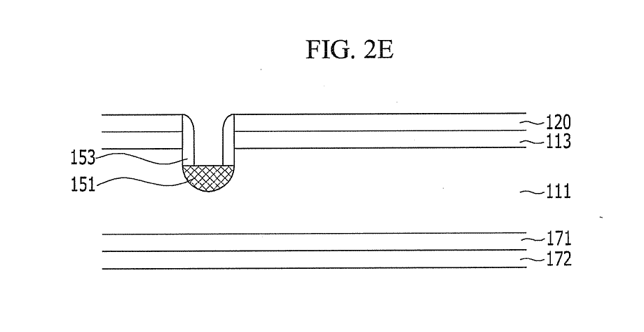

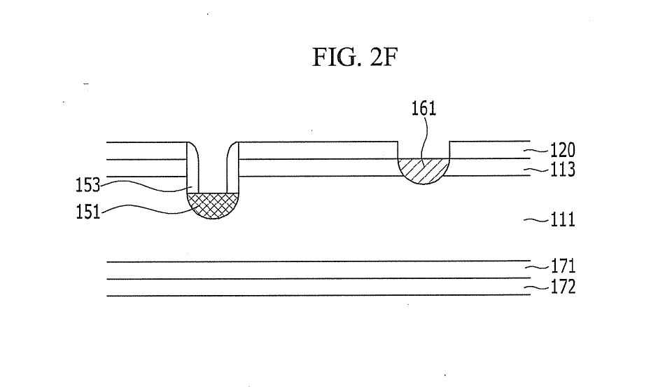

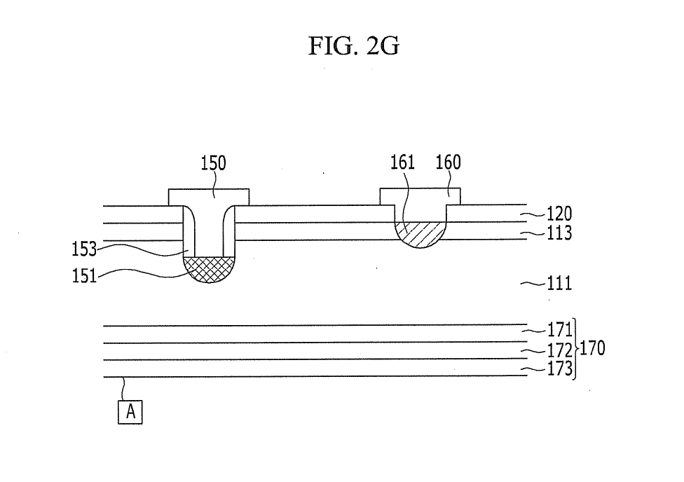

Referring to FIGS. 2A to 2G along with FIG. 1, a method of manufacturing a solar cell according to example embodiments is illustrated.

FIGS. 2A to 2G are cross-sectional views that sequentially show a process of manufacturing a solar cell according to example embodiments.

First, referring to FIG. 2A, a semiconductor layer 110 is provided. For example, a semiconductor layer 110 made of a silicon wafer may be provided. The semiconductor layer 110 may be doped with a p-type impurity or an n-type impurity, for example.

Then the semiconductor layer 110 is subjected to a surface texturing treatment. The surface-texturing treatment may be performed by a wet method using a strong acid such as nitric acid and hydrofluoric acid or a strong base such as potassium hydroxide and sodium hydroxide, or by a dry method using plasma.

Then, referring to FIG. 2B, the front and rear sides of a semiconductor substrate 110 are doped with an n-type impurity such as phosphorus (P) by an ion-impregnating process to form an N emitter layer 113 on the front side and an n+ layer 171 of the rear side of the semiconductor substrate 110. Accordingly, the semiconductor substrate 110 includes the semiconductor layer 111, the N emitter layer 113, and the n+ layer 171. In FIG. 2B, a process of forming the n+ layer 171 is shown, but it is not limited thereto and may be omitted.

The N emitter layer 113 and the n+ layer 171 are formed by ion-impregnating an n-type impurity, but it is not limited thereto and they may be formed by diffusing an n-type impurity. In addition, the N emitter layer 113 and the n+ layer 171 may be formed by ion-impregnating an n-type impurity after forming the following anti-reflection coating layer 120 and the dielectric layer 172 having a positive fixed charge.

Hereinafter, the n-type impurity, the semiconductor layer, the N emitter layer, and the n+ layer are the same as aforementioned, so further description is omitted.

Referring to FIG. 2C, an anti-reflection coating layer 120 is formed on the front side of the N emitter layer 113, and a dielectric layer 172 having a positive fixed charge is formed on the rear side of the n+ layer 171. FIG. 2C shows processes of forming the anti-reflection coating layer 120 and forming the dielectric layer 172 having a positive fixed but are not limited thereto and may be omitted. On the other hand, when the process of forming the dielectric layer 172 having a positive fixed charge is omitted, another process of forming an insulation layer having no positive fixed charge may be added instead of the process of forming the dielectric layer 172 having a positive fixed charge.

Hereinafter, the anti-reflection coating layer and the dielectric layer having a positive fixed charge may be the same as aforementioned, so further description is omitted.

The anti-reflection coating layer 120 and the dielectric layer 172 having a positive fixed charge may be formed by using silicon oxide and the like in a plasma enhanced chemical vapor deposition (PECVD) method. However, the anti-reflection coating layer 120 and the dielectric layer 172 having a positive fixed charge may be formed by using other materials and/or other methods.

Referring to FIG. 2D, a p+ region 151 is formed on the front side of the semiconductor layer 111.

First of all, the anti-reflection coating layer 120, the N emitter layer 113, and the front partial surface of the semiconductor layer 111 where the p+ region 151 is to be formed is etched, for example, in a process using photoresist patterning and dry etching. Next, the p+ region 151 may be formed by doping a p-type impurity such as boron (B) on the etched part of the semiconductor layer 111. The doping may be performed using a vapor diffusion method, a solid-phase diffusion method, an ion implantation method, and the like, but is not limited thereto.

Hereinafter, the p-type impurity and the p+ region are the same as aforementioned, so further description is omitted.

Next, referring to FIG. 2E, a spacer 153 is formed to contact the anti-reflection coating layer 120, the N emitter layer 113, the semiconductor layer 111, and the p+ region 151 at the etched portion to form the p+ region 151.

The spacer 153 may be formed using, for example, silicon nitride and the like in a plasma enhanced chemical vapor deposition (PECVD) method. However, the spacer 153 is not limited thereto, and may be formed using other materials in other methods.

Hereinafter, the spacer 153 may be the same as aforementioned, so further description is omitted.

Next, referring to FIG. 2F, an n+ region 161 is formed separate from the p+ region 151 on the front side of the semiconductor layer 111. FIG. 2F provides a process of forming the n+ region 161, but is not limited thereto and may be omitted.

First, an anti-reflection coating layer 120 is etched where the n+region 161 is to be formed, for example, by a process using photoresist patterning and a dry etching method. Then, the n+ region 161 may be formed by doping an n-type impurity such as phosphorous on the etched part of the semiconductor layer 111. The doping may be performed in a vapor diffusion method, a solid-phase diffusion method, an ion implantation method, and the like, but is not limited thereto. On the other hand, when a process of forming the n+ region is omitted, the second electrode is directly formed on the N emitter layer 113 after the dry etching.

Hereinafter, the n-type impurity and the n+ region may be the same as aforementioned, so further description is omitted.

Referring to FIG. 2G, a first electrode 150 is formed on the p+ region 151, a second electrode 160 is formed on the n+ region 161, and a positive (+) voltage-applied reflective layer 173 is formed beneath the dielectric layer 172 having a positive fixed charge. FIG. 2G shows a process of forming the positive (+) voltage-applied reflective layer 173, but it is not limited thereto and may be omitted.

The first electrode 150, the second electrode 160, and reflective layer 173 may be formed, for example, by sputtering aluminum and the like. The part where the first and second electrodes 150 and 160 are not formed may be removed after the sputtering using a process involving photoresist patterning and etching.

In addition, the reflective layer 173 may be connected to an electricity supplier A applying a positive (+) voltage.

However, they are not limited thereto, and the first and second electrodes 150 the 160 and the reflective layer 173 may be formed using other materials and/or other methods.

Hereinafter, the first and second electrodes and the reflective layer may be the same as aforementioned, so further description is omitted.

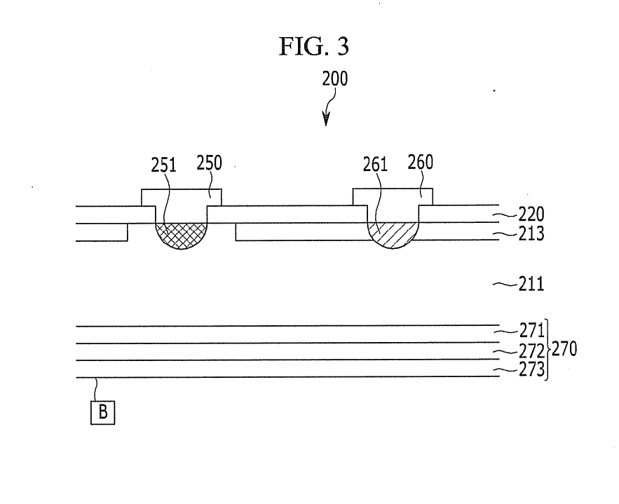

Next, referring to FIG. 3, a solar cell according to example embodiments is illustrated.

FIG. 3 is a cross-sectional view showing a solar cell 200 according to example embodiments.

Hereinafter, a light-absorbing surface receiving solar energy in a semiconductor layer 211 is called a front side, while the other side thereof is called a rear side. Hereinafter, for the better understanding and ease of description, the relationship between the upper and lower positions is described from the center of the semiconductor layer 211, but is not limited thereto.

Referring to FIG. 3, a solar cell 200 according to example embodiments may include: a semiconductor layer 211; an N emitter layer 213 formed where a p+ region 251 is not formed on the front side of the semiconductor layer 211; an anti-reflection coating layer 220 formed on the front side of the N emitter layer 213 and on the front side of the semiconductor layer 211 where the N emitter layer 213 is not formed; a p+ region 251 formed on the front side of the semiconductor layer 211 and penetrating the anti-reflection coating layer 220 and contacting the semiconductor layer 211; a first electrode 250 electrically connected to the p+region 251; an n+ region 261 formed on the front side of the semiconductor layer 211 having the N emitter layer 213 and penetrating the anti-reflection coating layer 220 and electrically connected to the semiconductor layer 211 but formed separate from the p+ region 251; a second electrode 260 electrically connected to the n+ region 261; and an auxiliary layer 270 inducing an N+ back surface field (BSF) formed on the rear side of the semiconductor layer 211. The auxiliary layer 270 may include an n+ layer 271, a dielectric layer 272 having a positive fixed charge, a positive (+) voltage-applied reflective layer 273, or a combination thereof. The reflective layer 273 is connected to an electricity supplier (B) applying a positive (+) voltage.

FIG. 3 shows an anti-reflection coating layer 220 and an n+ region 261. However, the anti-reflection coating layer 220 and the n+ region 261 are not limited thereto and may be selectively omitted.

In addition, FIG. 3 shows an n+ layer 271, a dielectric layer 272 having a positive fixed charge, and a positive (+) voltage-applied reflective layer 273. However, the n+ layer 271, the dielectric layer 272 having a positive fixed charge, and the positive (+) voltage-applied reflective layer 273 are not limited thereto and may be selectively omitted. When the positive (+) voltage-applied reflective layer 273 is omitted, an electricity supplier (B) applying a positive (+) voltage to the reflective layer 273 may also be omitted. On the other hand, when the dielectric layer 272 having a positive fixed charge is omitted, an insulation layer having no positive fixed charge may be included instead of the dielectric layer 272 having a positive fixed charge.

Hereinafter, the semiconductor layer, the N emitter layer, the anti-reflection coating layer, the p+ region, the first electrode, the n+ region, the second electrode, the auxiliary layer inducing an N+ back surface field (BSF), the n+ layer, the dielectric layer having a positive fixed charge, the positive (+) voltage-applied reflective layer, and the electricity supplier are the same as illustrated.

On the front side of the semiconductor layer 211, an N emitter layer 213 is formed where no p+ region 251 is formed.

On the front side of the N emitter layer 213 and the front side of the semiconductor layer 211 where the N emitter layer 213 is not formed, an anti-reflection coating layer 220 is formed. FIG. 3 shows a solar cell 200 including an anti-reflection coating layer 220, but the reflection coating layer 220 is not limited thereto and may be omitted.

On the front side of the semiconductor layer 211 where the N emitter layer 213 is not formed, a p+ region 251 is formed to penetrate the anti-reflection coating layer 220 and contact the semiconductor layer 211.

On the p+ region 251, a first electrode 250 is formed.

On the front side of the semiconductor layer 211 where the N emitter layer 213 is formed, an n+ region 261 is formed separate from the p+ region 251 to penetrate the anti-reflection coating layer 220 and to be electrically connected to the semiconductor layer 211.

On the n+ region 261, a second electrode 260 is formed.

On the back surface of the semiconductor layer 211, an auxiliary layer 270 inducing an N+ back surface field (BSF) is formed on the rear side of the semiconductor layer 211.

In FIG. 3, an n+ layer 271, a dielectric layer 272 having a positive fixed charge, and a positive (+) voltage-applied reflective layer 273 as the auxiliary layer 270 are shown, but they are not limited thereto and may be selectively omitted.

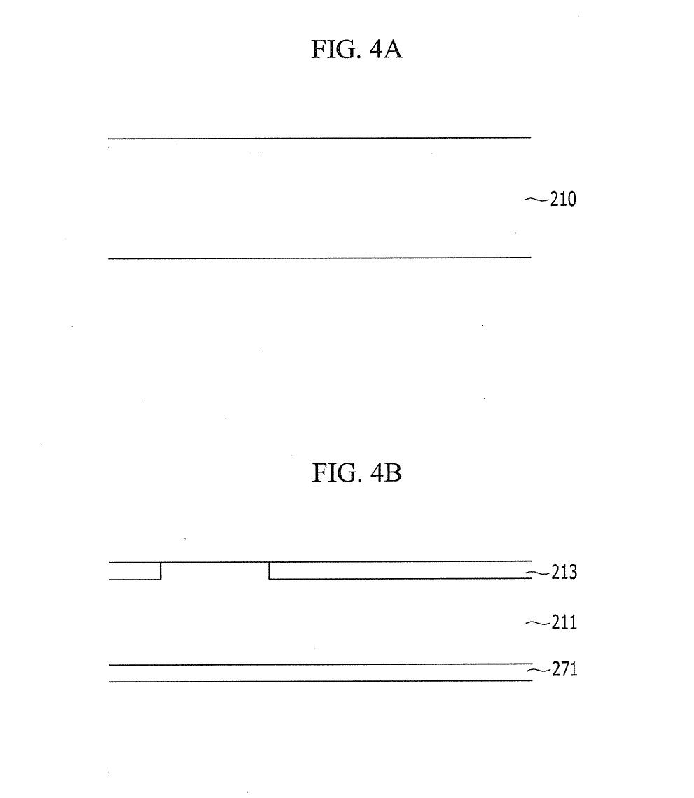

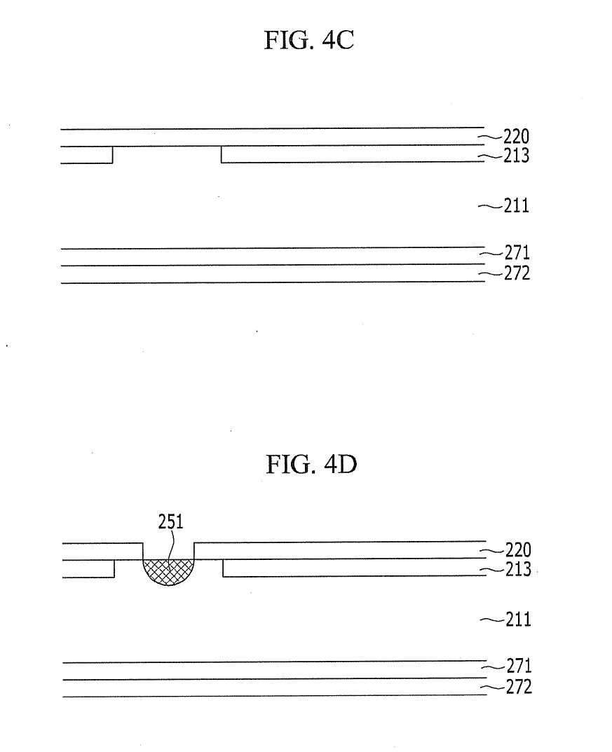

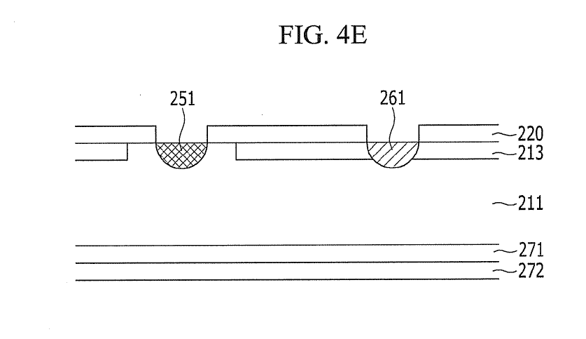

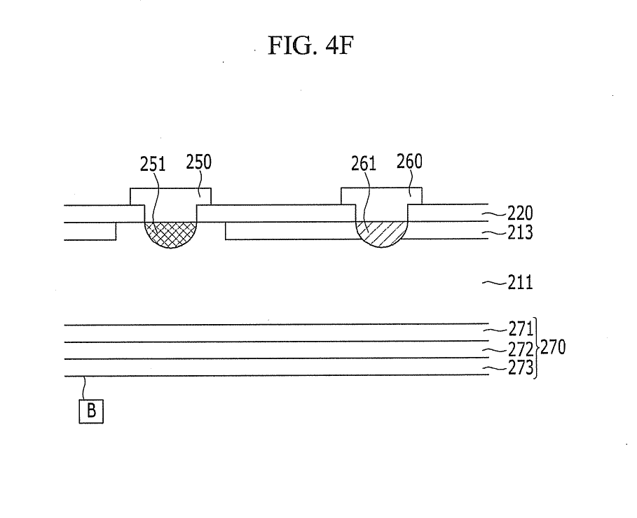

Hereinafter, a method of manufacturing a solar cell according to example embodiments is illustrated, referring to FIGS. 4A to 4F along with FIG. 3.

FIGS. 4A to 4F are cross-sectional views that sequentially show a process of manufacturing a solar cell according to example embodiments.

First, referring to FIG. 4A, a semiconductor substrate 210 is prepared. Hereinafter, a process of preparing the semiconductor substrate and the semiconductor substrate are the same as aforementioned so duplicative descriptions are omitted.

Referring to FIG. 4B, on the front side of the semiconductor substrate 210 except for where a p+ region is to be formed and on the rear side of the semiconductor substrate 210, an n-type impurity such as phosphorous (P) is ion-implanted for doping to form an N emitter layer 213 on the front side of the semiconductor substrate 210 and an n+ layer 271 on the rear side of the semiconductor substrate 210. When the front side of the semiconductor substrate 210 is doped, a mask may cover where the doping is not to be performed. In this way, the semiconductor substrate 210 may include a semiconductor layer 211, an N emitter layer 213, and an n+ layer 271. In FIG. 4B, a process of forming the n+ layer 271 is shown, but it is not limited thereto and may be omitted.

Hereinafter, a process of forming the N emitter layer and the n+ layer, and the n-type impurity, the semiconductor layer, the N emitter layer, and the n+ layer are the same as described above so duplicative descriptions are omitted.

Referring to FIG. 4C, on the front side of the N emitter layer 213 and the front side of the semiconductor layer 211 having no N emitter layer 213, an anti-reflection coating layer 220 is formed. On the rear side of the n+ layer 271, a dielectric layer 272 having a positive fixed charge is formed. In FIG. 4C, a process of forming the anti-reflection coating layer 220 and the dielectric layer 272 having a positive fixed charge are illustrated, but it is not limited thereto and may be omitted. On the other hand, when forming the dielectric layer 272 having a positive fixed charge is omitted, an insulation layer having no positive fixed charge may be additionally formed instead of forming the dielectric layer 272 having a positive fixed charge.

Hereinafter, a process of forming the anti-reflection coating layer and the dielectric layer having a positive fixed charge, the anti-reflection coating layer, and the dielectric layer having a positive fixed charge are the same as illustrated above.

Then, referring to FIG. 4D, on the front side of the semiconductor layer 211, a p+ region 251 is formed.

First of all, the part of the anti-reflection coating layer 220 where a p+ region 251 is to be formed, and in particular, where the N emitter layer 213 is not formed, is etched by using a photoresist patterning and a dry etching method. Then, a p+ region 251 may be formed by doping a p-type impurity such as boron (B) on the etched part of the semiconductor layer 211. The doping may include a vapor diffusion method, a solid-phase diffusion method, an ion implantation method, and the like, but is not limited thereto.

Hereinafter, a process of forming the p+ region, the p-type impurity, and the p+ region are the same as aforementioned above.

Referring to FIG. 4E, an n+ region 261 is separately formed from a p+ region 251 on the front side of the semiconductor layer 211 having the N emitter layer 213. In FIG. 4E, a process of forming the n+ region 261 is illustrated, but it is not limited thereto and may be omitted.

Hereinafter, a process of forming the n+ region, and the n+ region are the same as illustrated above.

Referring to FIG. 4F, a first electrode 250 is formed on the p+ region 251, a second electrode 260 is formed on the n+ region 261, and a positive (+) voltage-applied reflective layer 273 is formed beneath the dielectric layer 272 having a positive fixed charge. In FIG. 4F, a process of forming the positive (+) voltage-applied reflective layer 273 is illustrated, but it is not limited thereto and may be omitted.

The reflective layer 273 may be connected to an electricity supplier (B) applying a positive (+) voltage.

Hereinafter, a process of forming the first and second electrodes and the reflective layer, and the first electrode, the second electrode, the reflective layer, and the electricity supplier are the same as aforementioned.

While some example embodiments have been particularly shown and described, it will be understood by one of ordinary skill in the art that variations in form and detail may be made therein without departing from the spirit and scope of the claims.

What is claimed is:

1. A solar cell comprising:
a semiconductor substrate;
an N emitter layer formed on a light-absorbing surface of the semiconductor substrate;
a p+ region formed on the light-absorbing surface of the semiconductor substrate;
a first electrode electrically connected to the p+ region;
a second electrode separated from the first electrode on the light-absorbing surface of the semiconductor substrate and electrically connected to the N emitter layer; and
an auxiliary layer inducing an N+back surface field (BSF) formed on the opposite surface to the light-absorbing surface of the semiconductor substrate.

2. The solar cell of claim 1, wherein the solar cell further comprises a spacer between the N emitter layer and the first electrode.

3. The solar cell of claim 2, wherein the spacer comprises:
a material selected from one of aluminum oxide (Al₂O₃), silicon oxide (SiO₂), titanium oxide (TiO₂ or TiO₄), magnesium oxide (MgO), cerium oxide (CeO₂), aluminum nitride (AlN), silicon nitride (SiNₓ), aluminum oxynitride (AlON), silicon oxynitride (SiON), titanium oxynitride (TiON), and a combination thereof.

4. The solar cell of claim 1, wherein the N emitter layer is separated from the p+ region and the first electrode.

5. The solar cell of claim 1, wherein the auxiliary layer comprises one of a n+ layer, a dielectric layer having a positive fixed charge, a positive (+) voltage-applied reflective layer, and a combination thereof.

6. The solar cell of claim 5, wherein the n+ layer is formed by a process including one of:
a vapor diffusion method using one of PH₃, AsH₃, SbCl₃, POCl₃, and a combination thereof;
a solid-phase diffusion method using one of phosphosilicate glass (PSG), arsenic silicon glass (ASG), and a combination thereof;
an ion implantation method using arsenic (As), phosphorus (P), and a combination thereof;
and a combination thereof.

7. The solar cell of claim 5, wherein the n+ layer includes a doping concentration ranging from about 1×10¹⁶ cm⁻³ to about 1×10²¹ cm⁻³.

8. The solar cell of claim 5, wherein the n+ layer includes a sheet resistance ranging from about 10 Ω to about 90,000 Ω.

9. The solar cell of claim 5, wherein the dielectric layer comprises one of an oxide, a nitride, an oxynitride, and a combination thereof.

10. The solar cell of claim 5, wherein the dielectric layer has a positive fixed charge density ranging from about 1×10¹⁰ cm⁻² to about 1×10¹⁵ cm⁻².

11. The solar cell of claim 5, wherein the dielectric layer has a thickness ranging from about 1 nm to about 10,000 nm.

12. The solar cell of claim 5, wherein the reflective layer comprises one of Al, Au, Pt, Ag, Cu, and a combination thereof.

13. The solar cell of claim 5, wherein the reflective layer is configured to receive an applied voltage ranging from about +0.1 V to about +50 V.

14. The solar cell of claim 5, wherein the reflective layer has a thickness ranging from about 1 nm to about 10,000 nm.

15. A method of manufacturing a solar cell, comprising;
preparing a semiconductor substrate;
forming an N emitter layer on a light-absorbing surface of the semiconductor substrate;
forming an auxiliary layer inducing an N+ back surface field (BSF) on an opposite surface to the light-absorbing surface of the semiconductor substrate;
forming a p+ region on the light-absorbing surface of the semiconductor substrate;
forming a first electrode electrically connected to the p+ region; and
forming a second electrode separate from the first electrode and electrically connected to the N emitter layer on the light-absorbing surface of the semiconductor substrate.

16. The method of claim 15, wherein the auxiliary layer comprises one of an n+ layer, a dielectric layer having a positive fixed charge, a positive (+) voltage-applied reflective layer, and a combination thereof.
